(19) United States
(12) Patent Application Publication
(10) Pub. No.: US 2017/0098653 A1
(43) Pub. Date: Apr. 6, 2017

(54) METHODS OF MANUFACTURING SEMICONDUCTOR DEVICES

(71) Applicant: Samsung Electronics Co., Ltd., Suwon-si (KR)

(72) Inventors: Young-Ho Koh, Seongnam-si (KR); Hye-Sung Park, Siheung-si (KR); Byoung-Ho Kwon, Hwaseong-si (KR); Jong-Hyuk Park, Hwaseong-si (KR); Bo-Un Yoon, Seoul (KR); ln-Seak Hwang, Suwon-si (KR)

(21) Appl. No.: 15/182,637

(22) Filed: Jun. 15, 2016

(30) Foreign Application Priority Data
Oct. 2, 2015 (KR) 10-2015-0139049

(51) Int. Cl. H01L 27/108; H01L 21/311; H01L 21/3105

(52) U.S. Cl. CPC H01L 27/10894; H01L 21/31056; H01L 21/31138; H01L 27/10897; H01L 27/10814; H01L 27/10823

(57) ABSTRACT

Methods of manufacturing a semiconductor device are provided. Methods may include forming first to third regions having densities different from one another on a substrate, covering the first to third regions to form an upper interlayer insulating film including a low step portion and a high step portion higher than the low step portion, forming an organic film on the upper interlayer insulating film, removing a part of the organic film to expose an upper surface of the high step portion, removing the high step portion so that an upper surface of the high step portion is disposed on at least the same line as the organic film disposed on the upper surface of the lower step portion, removing the remaining part of the organic film to expose the upper surface of the upper interlayer insulating film and flattening the upper surface of the upper interlayer insulating film.

This application claims priority from Korean Patent Application No. 10-2015-0139049 filed on Oct. 2, 2015 in the Korean Intellectual Property Office, the disclosure of which is incorporated herein by reference in its entirety.

### BACKGROUND

In recent years, along with large capacity and high integration of semiconductor devices, design rules also have continuously decreased. Such a tendency also occurs in a dynamic random access memory (DRAM), which is a type of semiconductor memory device. A capacitance of a certain level or more for each cell may be required for operation of the DRAM device. An increase in the capacitance may increase an amount of electric charge stored in a capacitor, which may improve refresh characteristics of the semiconductor device. The improved refresh characteristics of the semiconductor device may improve the yield of the semiconductor device.

Meanwhile, various different studies have been made to increase the capacity of the capacitor. For example, it is possible to increase an aspect ratio of a storage electrode of the capacitor. For example, a three-dimensional structure of a cylinder from may be adopted as the shape of the storage electrode. Further, a high dielectric constant film may be used as a dielectric film of the capacitor.

However, one problem that may occur includes a defocus shape that may arise because of a difference in height for each region of the wafer when forming a pattern in processes that occur after the capacitor is formed.

### SUMMARY

Aspects of the present inventive concept provide methods of manufacturing a semiconductor device with improved reliability.

Aspects of the present inventive concept provide methods of manufacturing a semiconductor device capable of manufacturing a semiconductor device with improved reliability.

Aspects of the present inventive concept provide methods of manufacturing a semiconductor device capable of uniformly forming the heights of each region of the wafer.

According to an aspect of the present inventive concept, there are provided methods of manufacturing a semiconductor device, Such methods may include forming first to third regions having densities different from one another on a substrate, covering the first to third regions to form an upper interlayer insulating film including a low step portion and a high step portion higher than the low step portion, forming an organic film on the upper interlayer insulating film, removing a part of the organic film to expose an upper surface of the high step portion, removing the high step portion so that an upper surface of the high step portion is disposed on at least the same line as the organic film disposed on the upper surface of the lower step portion, removing the remaining part of the organic film to expose the upper surface of the upper interlayer insulating film and flattening the upper surface of the upper interlayer insulating film.

In some embodiments of the inventive concept, the organic film does not contain silicon (Si).

In some embodiments of the inventive concept, the formation of the organic film includes conformally forming the organic film on the upper interlayer insulating film.

In some embodiments of the inventive concept, the first region has a density lower than that of the third region, the first region is a memory cell array region, and the third region is a wafer edge region.

In some embodiments of the inventive concept, the flattening of the upper surface of the upper interlayer insulation film includes disposing the upper surface of the memory cell array and the upper surface of the upper interlayer insulating film on the same plane.

In some embodiments of the inventive concept, the removal of a part of the organic film includes removing a part of the organic film through chemical mechanical polishing process.

In some embodiments of the inventive concept, the formation of the upper interlayer insulating film includes forming the low step portion on the second region and forming the high step portion on the third region.

In some embodiments of the inventive concept, the removal of the high step portion includes removing the high step portion by etching.

In some embodiments of the inventive concept, the removal of the high step portion includes removing the high step portion by anisotropic etching.

In some embodiments of the inventive concept, flattening of the upper surface of the upper interlayer insulation film includes flattening the upper surface of the upper interlayer insulating film through a chemical mechanical polishing process.

According to an aspect of the present inventive concept, there are provided methods of manufacturing a semiconductor device. Such methods may include forming a memory cell array region, a peripheral region and a wafer edge region on a substrate, forming an interlayer insulating film that covers the memory cell array region, the peripheral region and the wafer edge region, forming an organic film on the interlayer insulating film, removing the organic film disposed in the memory cell array region and the wafer edge region to expose a part of an upper surface of the interlayer insulating film, etching a part of the interlayer insulating film so that the partial upper surface of the interlayer insulating film covering the memory cell array region and the wafer edge region is disposed below the upper surface of the organic film disposed in the peripheral region, removing the organic film disposed in the peripheral region and flattening the interlayer insulating film formed in the memory cell array region, the peripheral region and the wafer edge region.

In some embodiments of the inventive concept, the organic film does not contain silicon (Si).

In some embodiments of the inventive concept, the removal of the organic film disposed in the memory cell array region and the wafer edge region includes use of a chemical mechanical polishing process.

In some embodiments of the inventive concept, etching of the interlayer insulation film includes an anisotropic etching using a dry etching.

In some embodiments of the inventive concept, flattening of the interlayer insulating film includes use of a chemical mechanical polishing process.

Some embodiments of the inventive concept include methods of manufacturing a semiconductor device. Methods may include forming an interlayer insulating film that covers a plurality of regions having different densities from one another, forming an organic film on the interlayer insulating film, removing the organic film from less than all of the plurality of regions to expose a portion of an upper surface of the interlayer insulating film, etching a part of the interlayer insulating film so that the partial upper surface of the interlayer insulating film is at a height that is below an upper surface of the organic film on at least one of the plurality of regions, removing the organic film from the at least one of the plurality of regions and flattening the upper surface of the interlayer insulating film on the plurality of regions.

In some embodiments, the organic film does not contain silicon (Si) and the formation of the organic film comprises conformally forming the organic film on the upper interlayer insulating film.

Some embodiments provide that the less than all of the plurality of regions have a first density and the at least one of the plurality of regions has a second density that is greater that the first density.

In some embodiments, flattening the upper surface of the upper interlayer insulation film comprises flattening the upper surface of the upper interlayer insulating film by performing a chemical mechanical polishing process.

In some embodiments, etching the part of the interlayer insulation film comprises anisotropically etching the part of the interlayer insulating film using a dry etching.

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is a schematic diagram for explaining a semiconductor device according to some embodiments of the present inventive concept.

FIG. 2 is a conceptual diagram for explaining the semiconductor device according to some embodiments of the present inventive concept.

FIG. 3 is a layout diagram illustrating a part of a first region of FIG. 2.

FIG. 4 is a cross-sectional view taken along line B-B of FIG. 3.

FIG. 5 is a circuit diagram for explaining a first region of FIG. 2.

FIGS. 6 to 21 are cross-sectional views of intermediate steps for describing methods of manufacturing the semiconductor device according to some embodiments of the present inventive concept.

FIGS. 22 to 27 are cross-sectional views of intermediate steps for illustrating methods of manufacturing a semiconductor device according to some embodiments of the present inventive concept.

FIGS. 28 to 32 are cross-sectional views of intermediate steps for illustrating methods of manufacturing a semiconductor device according to some embodiments of the present inventive concept.

FIG. 33 is a block diagram of an example of an electronic system including the semiconductor device manufactured by the methods of manufacturing the semiconductor device according to some embodiments of the present inventive concept.

FIG. 34 is a block diagram illustrating an example of a memory card that includes a semiconductor device manufactured by the methods of manufacturing the semiconductor device according to the embodiments of the present inventive concept.

FIG. 35 is an example of a semiconductor system to which the semiconductor devices according to some embodiments of the present inventive concept are applicable.

### DETAILED DESCRIPTION OF THE EMBODIMENT

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the disclosure to those skilled in the art, and the present inventive concept will only be defined by the appended claims. In the drawings, the thickness of layers and regions are exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

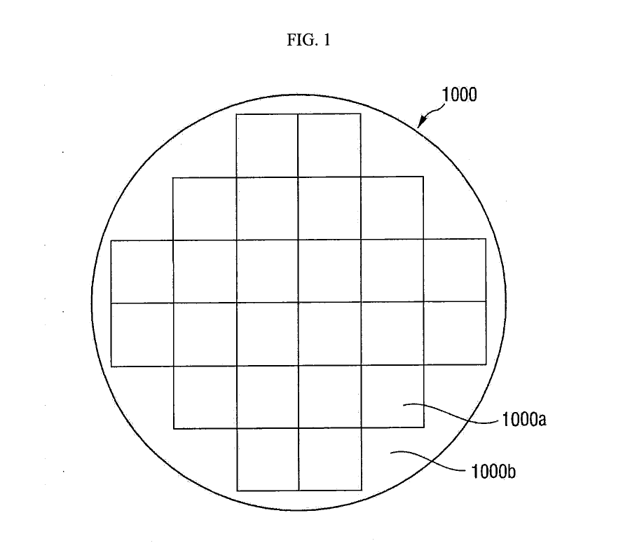

A semiconductor device according to some embodiments of the present inventive concept will be described referring to FIGS. 1 to 5.

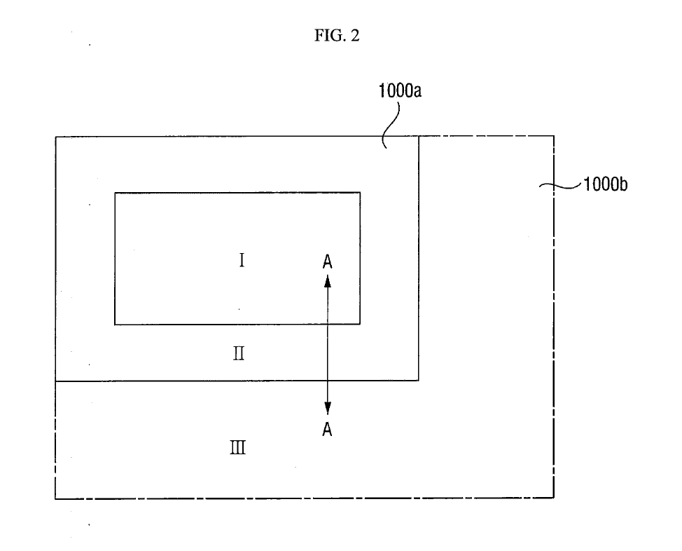

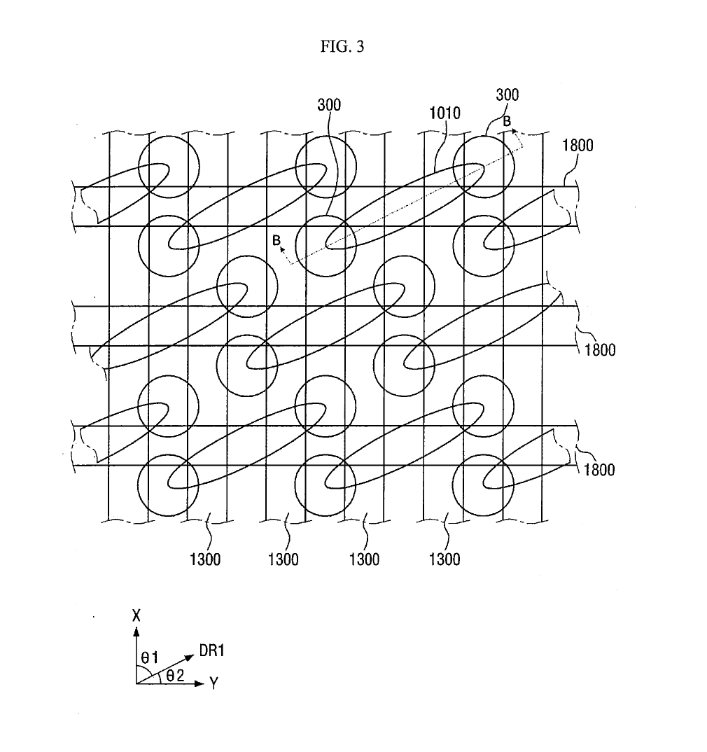

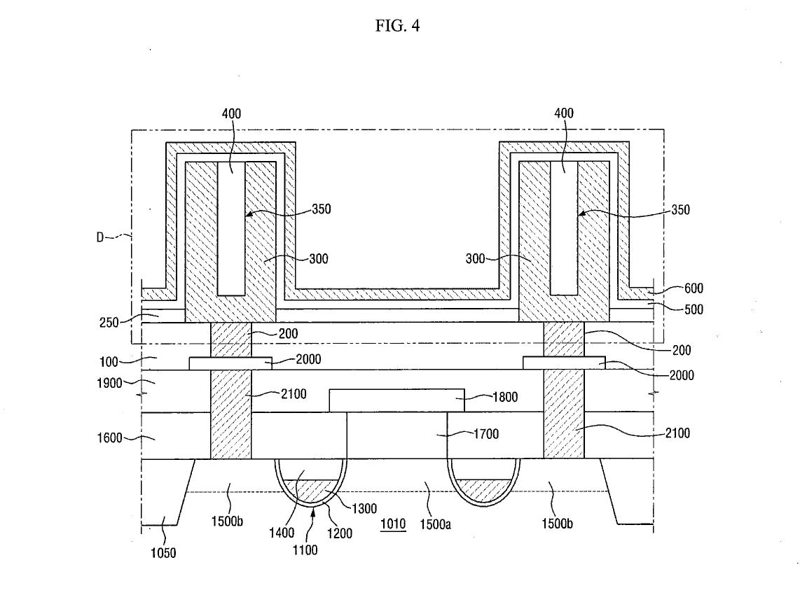

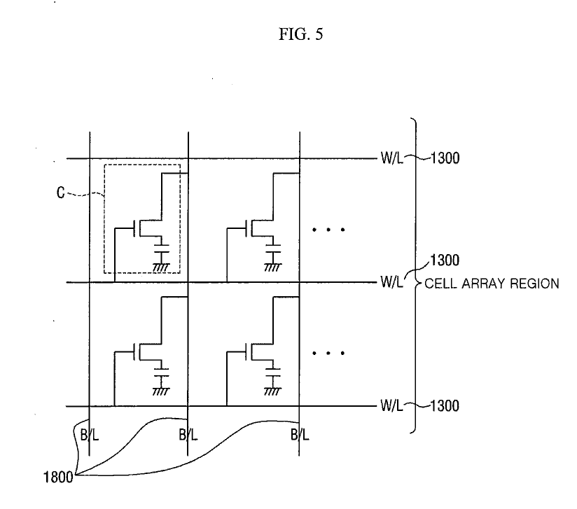

FIG. 1 is a schematic diagram for explaining a semiconductor device according to some embodiments of the present inventive concept. FIG. 2 is a conceptual diagram for explaining the semiconductor device according to some embodiments of the present inventive concept. FIG. 3 is a layout diagram illustrating a part of a first region of FIG. 2. FIG. 4 is a cross-sectional view taken along line B-B of FIG. 3. FIG. 5 is a circuit diagram for explaining a first region of FIG. 2.

Referring to FIGS. 1 and 2, a wafer 1000 includes a DRAM region 1000a and a wafer edge region 1000b. The wafer 1000 may include a plurality of DRAM regions 1000a in which each of DRAMs is formed, and a wafer edge region 1000b in which the DRAM is not formed.

In some embodiments, the DRAM region 1000a and the edge region 1000b illustrated on the wafer 1000 are schematically illustrated for explanation, and the technical idea of the present inventive concept is not limited thereto. Therefore, a DRAM region 1000a having arrangement and number different from the illustrated configuration, and an edge region 1000b including an additional region may be disposed on the wafer 1000.

The DRAM region 1000a includes a first region I, and a second region II that wraps around the first region I. The edge region 1000b may include a third region III that wraps around a part of the second region II. In some embodiments, the first region I, the second region II and the third region III are illustrated as being adjacent one another, but the technical idea of the present inventive concept is not limited thereto. Therefore, the first region I, the second region II and the third region III may be regions spaced apart from one another. Further, although a configuration in which the second region II wraps around a part of the first region I and the third region III wraps around a part of the second region II is illustrated, the technical of the present inventive concept is not limited thereto.

The first region I may be a memory cell array region and may have a first density. The second region II may be a peripheral region and may have a second density. The third region III may be an edge region of the wafer that does not include the pattern and may have a third density. The third density may be, but not limited to, a density higher than the first and second densities.

However, since the present inventive concept can solve defects of a chemical mechanical polish (CMP) process that may occur depending on the density difference of the first to third regions I, II and III, the densities of the first to third regions I, II and III will be described by being regarded as different from one another. However, the present inventive concepts are not limited thereto.

Meanwhile, the memory cell array region may be a region in which an element for storing data is disposed, and the peripheral region may be a region in which an element for controlling the recording and reading of data to the memory cell array region or from the memory cell array region is disposed. However, the present inventive concept is not limited thereto.

Meanwhile, in the detailed description of the present inventive concept, the memory cell array region may be referred to as a first region I, the peripheral region may be referred to as a second region II, and the wafer edge region may be referred to as a third region III, but the present inventive concept is not limited thereto.

Next, the memory cell array region included in the first region I will be described with reference to FIGS. 3 to 5.

The memory cell array region described through FIGS. 3 to 5 is an example, and the technical idea of the present inventive concept is not limited thereto. Accordingly, various regions capable of storing the data may be regions corresponding to the memory cell array region of the present inventive concepts.

Referring to FIGS. 3 to 5, a semiconductor device of the memory cell array region included in the first region I includes a substrate 1000, an interlayer insulating film 100, a first metal contact plug 200, an etching stop film 250, a first lower electrode 300, a first trench 350, a first supporter 400, a dielectric film 500 and an upper electrode 600.

The substrate 1000 may be divided into an element isolation region 1050 and an active region 1010. The active region 1010 is defined by forming the element isolation region 1050 in the substrate 1000. Specifically, referring to FIG. 3, the active region 1010 is formed to extend in a first direction DR1, a gate electrode (i.e., a word line) 1300 is formed to extend in an X direction forming an acute angle with the first direction DR1, and a bit line 1800 is formed to extend in a Y direction forming an acute angle with the first direction DR1. Cylinder-shaped lower electrodes 300 may be formed at both ends of the active region 1010.

As used herein, an angle of a case where “a specific direction and another specific direction form a predetermined angle” means a smaller angle of two angles which are generated by intersection of the two directions. For example, when the angles capable of being generated by intersection of the two directions are 120° and 60°, the angle means 60°. Therefore, as illustrated in FIG. 3, an angle formed between the first direction DR1 and the X direction is θ1, and an angle formed between the first direction DR1 and the Y direction is θ2. Some embodiments provide that θ1 and/or θ2 form an acute angle to maximally ensure an interval between a bit line contact 1700 for connecting the active region 1010 with the bit line 1800, and a contact plug 2100 for connecting the active region 1010 with the storage element. Each of θ1 and θ2 may be, but not limited to, for example, 45° and 45°, 30° and 60° or 60° and 30°.

Specifically, the substrate 1000 may be a rigid substrate such as a silicon substrate, a silicon on insulator (SOI) substrate, a gallium arsenide substrate, a silicon germanium substrate, a ceramic substrate, a quartz substrate and/or a display glass substrate, or a flexible plastic substrate such as a polyimide, polyester, polycarbonate, polyethersulfone, polymethylmethacrylate, polyethylene naphthalate and/or polyethyleneterephthalate.

Referring to FIG. 4, an embedded trench 1100 is formed in the active region 1010, and a gate insulating film 1200, a gate electrode 1300 and a capping pattern 1400 may be sequentially formed inside the embedded trench 1100. A first source/drain region 1500a and a second source/drain region 1500b may be formed on both sides of the embedded trench 1100. The gate electrode 1300, the first source/drain region 1500a and the second source/drain region 1500b may operate as a buried channel array transistor (BCAT). However, the technical idea of the present inventive concept is not limited thereto.

The first insulating layer 1600 may be formed on the BCAT, and a bit line contact 1700 connected to the bit line 1800 may be formed through the first insulating layer 1600. The second insulating layer 1900 may be formed to cover the bit line 1800, and a contact plug 2100 connected to a landing pad 2000 may be formed through the second insulating layer 1900.

The interlayer insulating film 100 may be formed on the substrate 1000. Specifically, the interlayer insulating film 100 may be formed on the second insulating layer 1900 and the landing pad 2000. The interlayer insulating film 100 may be formed, using a silicon oxide such as borosilicate glass (BSG), phosphosilicate glass (PSG), borophosphosilicate glass (BPSG), undoped silicate glass (USG), tetraethylorthosilicate glass (TEOS) and/or high density plasma-CVD (HDP-CVD).

The first metal contact plug 200 may be formed through the interlayer insulating film 100. The first metal contact plug 200 may electrically connect elements between the interlayer insulating films 100. The first metal contact plug 200 may contain, but not limited to, a metal, e.g., tungsten (W).

The etching stop film 250 may be located on the interlayer insulating film 100 on the side surface of the first lower electrode 300. The etching stop film 250 may be formed of a material having a poor etching ratio and may serve as an end point film of the etching process. In some embodiments, the etching stop film 250 may contain, for example, SiON and/or SiN. In some embodiments, the etching stop film 250 may be omitted.

The first lower electrode 300 may be formed on the first metal contact plug 200. The first lower electrode 300 may have a cylindrical shape. The first lower electrode 300 may act as a capacitor together with the upper electrode 600 and the dielectric film 500. The first lower electrode 300 may be made of a first conductive material. For example, the first conductive material may be TiN, TaN, W, Ru and/or Pt. However, the present inventive concept is not limited thereto.

The first lower electrode 300 may be in the form of an elongate stack. Some embodiments provide that a plurality of first lower electrodes 300 may be arranged and formed. A first supporter 400 may be formed inside the first lower electrode 300. The dielectric film 500 and the upper electrode 600 may be formed on the first lower electrode 300 and the first supporter 400 later. Referring to FIG. 2, the first lower electrode 300 may be formed at both ends of the active region 1010.

The first trench 350 may be formed in the first lower electrode 300. Specifically, the first lower electrode 300 may consequently have a cylindrical shape by the presence of the first trench 350. One of the reasons for forming the first trench 350 on the first lower electrode 300 is that it is possible to reduce the first conductive material which forms the first lower electrode 300. However, since the formation of the trench may be weakness of the capacitor structure, this may be compensated using a supporter.

The first supporter 400 may be formed in the first trench 350. Specifically, the first supporter 400 may completely fill the interior of the trench. An upper surface of the first supporter 400 may be formed on the same plane as an upper surface of the first lower electrode 300. The “same plane” a concept that includes a fine step between the upper surface of the first supporter 400 and the upper surface of the first lower electrode 300. It is possible to prevent collapse of the first lower electrode 3001 using the first supporter 400. Specifically, the first internal supporter 400 may endure a tensile stress exerted on the first lower electrode 300.

The dielectric film 500 may cover the first lower electrode 300, the first supporter 400 and the etching stop film 250. The dielectric film 500 may serve to prevent the electric charge from passing between the first lower electrode 300 and the upper electrode 600. Although the dielectric film 500 does not allow the electric charge to pass, it may be charged by the voltage difference between the first lower electrode 300 and the upper electrode 600. The dielectric film 500 may be made up of Al₂O₃, HfO2, lantanide oxide, ZrO₂, Ta₂O₅, TiO₂, SrTiO3, BaSrTiO3 and combinations thereof. However, the present inventive concept is not limited thereto.

The upper electrode 600 may be formed on the dielectric film 500. The upper electrode 600 may form a capacitor together with the dielectric film 500 and the first lower electrode 300. That is, the upper electrode 600 may serve to collect static charge with the first lower electrode 300. The upper electrode 600 may be formed of a material similar to the first lower electrode 300. For example, the upper electrode 600 may contain TiN, TaN, W, Ru, Pt and the like. However, the present inventive concept is not limited thereto.

Referring to FIGS. 4 and 5 again, a part of the memory cell array region included in the first region I may also be expressed as a circuit diagram in which the word line 1300 and the bit line 1800 form a grid structure. The semiconductor device included in the memory cell array region may be a DRAM device in which a transistor and a capacitor are located between the grids of the word lines 1300 and the bit lines 1800.

Specifically, the gate insulating film 1200, the gate electrode 1300 and the capping pattern 1400 formed within the embedded trench 1100 may serve as a gate of the transistor in the cell of a part C in FIG. 5. Since there are two gates in FIG. 4, it can be understood as a cross-sectional view of two cells. A first source/drain region 1500a and a second source/drain region 1500b formed on both sides of the embedded trench 1100 may serve as a source or a drain of the transistor of the part C in FIG. 5. The first lower electrode 300, the dielectric film 500 and the upper electrode 600 may serve as the capacitor as the part C.

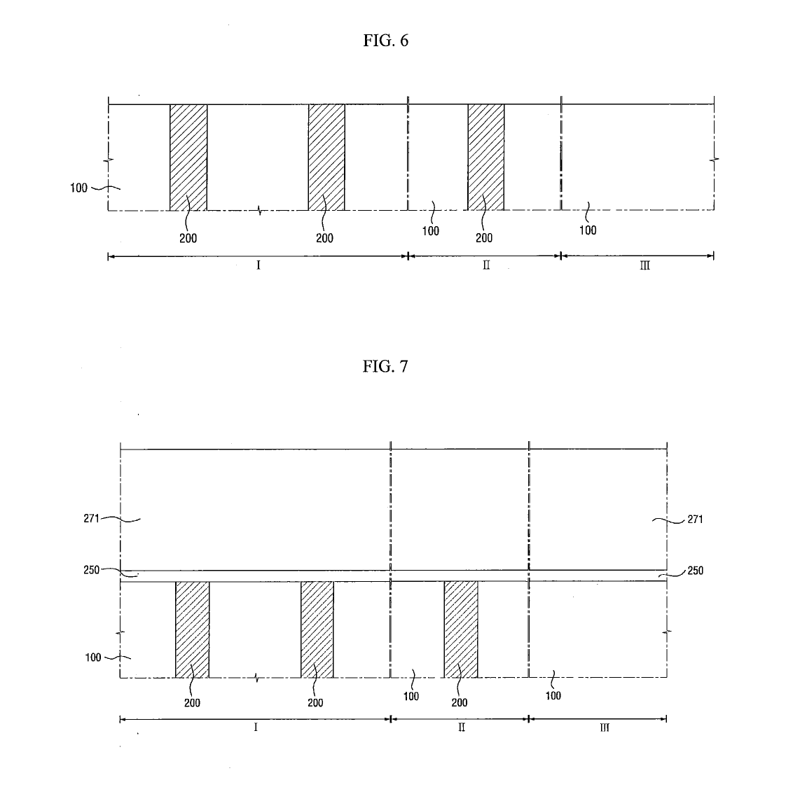

Next, methods of manufacturing the semiconductor device according to some embodiments of the present inventive concept will be described referring to FIGS. 6 to 21.

FIGS. 6 to 21 are cross-sectional views of intermediate operations for describing methods of manufacturing the semiconductor device according to some embodiments of the present inventive concept.

The cross-sectional views for describing the present embodiment may be cross-sectional views taken along the line A-A of FIG. 2. In this embodiment, although the first region I is illustrated as being relatively wider than the second and third regions II and III, this is for convenience of description, and the technical idea of the present inventive concept is not limited thereto.

Further, the first region I, the second region II and the third region III are illustrated as being successively disposed adjacent one another, but it is not limited thereto. Therefore, the first region I, the second region II and the third region III may also be adjacent one another and may be spaced apart from one another.

Further, the first region I and the third region III may be regions in which the same processes are simultaneously performed in the process of forming the capacitor. However, in the present inventive concept, although the process of forming the capacitor is described on the basis of the first region I, the technical idea of the present inventive concept is not limited thereto.

Specifically, referring to FIG. 6, the interlayer insulating film 100 is formed on the substrate 1000. Although it is not illustrated in FIG. 6, a transistor and a bit line (1800 in FIG. 3) may be located below the interlayer insulating film 100. The first metal contact plug 200 may be formed through the interlayer insulating film 100. The first metal contact plug 200 may contain a conductive material. Specifically, the first metal contact plug 200 may contain, for example, at least one of polysilicon, a metal silicide compound, a conductive metal nitride and/or a metal, but the present inventive concept is not limited thereto.

In some embodiments of the present inventive concept, the first metal contact plug 200 may be formed in the first region I and the second region II and may not be formed in the third region III, but it is not limited thereto.

In some embodiments of the present inventive concept, the first metal contact plug 200 may also be formed only in the first region I, but it is not limited thereto.

Next, referring to FIG. 7, an etching stop film 250 is formed to cover the interlayer insulating film 100 and the first metal contact plug 200. The etching stop film 250 may be formed of a material having a poor etching ratio and may serve as an end point film of the etching process. In this embodiment, the etching stop film 250, for example, may contain, but not limited to, SiON and/or SiN. In some embodiments of the present inventive concept, if necessary, formation of the etching stop film 250 may be omitted.

Next, a mold oxide layer 271 is formed on the etching stop film 250. The mold oxide layer 271 may be patterned later to provide a trench that is required to form the lower electrode. The mold oxide layer 271 is formed to have a sufficient height so that the first lower electrode 300 can be formed sufficiently long.

The etching stop film 250 and the mold oxide layer 271 may be formed on all of the first region I, the second region II and the third region II, but it is not limited thereto.

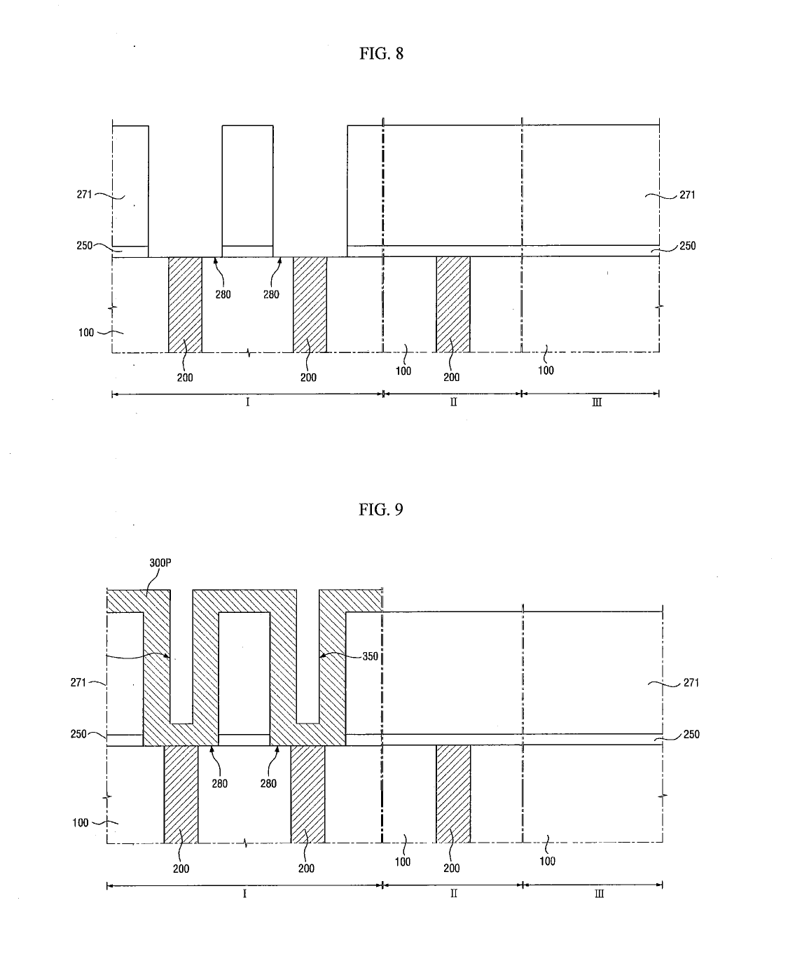

Next, referring to FIG. 8, the mold oxide layer 271 and the etching stop film 250 may be etched until the upper surface of the first metal contact plug 200 is exposed. Thus, a lower electrode hole 280 is formed in the mold oxide 270 as illustrated.

In some embodiments of the present inventive concept, the lower electrode hole 280 may be formed in the first region I and the third region III, but it is not limited thereto.

Next, specifically, referring to FIG. 9, a lower electrode film 300p may be formed in the first region I to cover the upper surfaces of the lower electrode hole 280 and the mold oxide 270. The lower electrode film 300p may be conformally formed along the shape of the mold oxide 270, as illustrated. As a method of forming the lower electrode film 300p, for example, a chemical vapor deposition (CVD) method, an atomic layer deposition (ALD) method and the like may be used, but the present inventive concept is not limited thereto.

Since the lower electrode film 300p is conformally formed along the shape of the molded oxide 270, the first trench 350 may be formed on the formed lower electrode film 300p as illustrated.

The lower electrode film 300p may be made of a first conductive material. For example, the first conductive material may be TiN, TaN, W, Ru and/or Pt. However, it is not limited thereto.

Meanwhile, although a configuration in which the lower electrode film 300p is formed in the first region I and is not formed in the second region II and the third region III is illustrated, the technical idea of the present inventive concept is not limited thereto.

Thus, in some embodiments of the present inventive concept, the lower electrode film 300p may be formed in the first to third regions I, II and III.

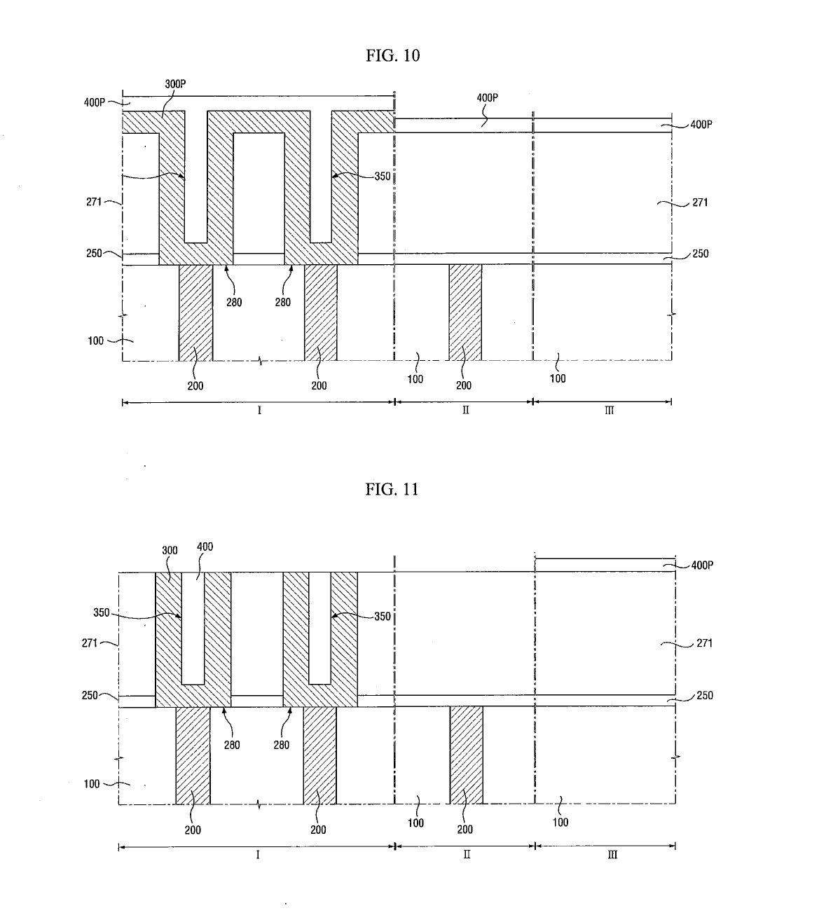

Next, referring to FIG. 10, a first supporter film 400p is formed to completely fill the first trench 350. Also, the first supporter film 400p may be formed to cover the upper surface of the lower electrode film 300p.

The first supporter film 400p may support the lower electrode film 300p and may contain a nitride.

Meanwhile, in this embodiment, although a configuration in which the first supporter film 400p is formed to support the lower electrode film. 300p is illustrated, the technical idea of the present inventive concept is not limited thereto.

Next, referring to FIG. 11, the lower electrode film 300p and the first supporter film 400p may be etched until the upper surface of the mold oxide 270 is exposed. Node separation between the cells is performed according to the etching.

Etching of the lower electrode film 300p and the first supporter film 400p may be performed using a chemical mechanical polishing (CMP) process. When the upper portion of the lower electrode film 300p is etched, the first lower electrode 300 may be formed. When the upper portion of the first supporter film 400p is etched, the first supporter 400 may be formed. The upper surface of the first supporter 400 may be in the same plane as the upper surface of the first lower electrode 300. The “same plane” is a concept that includes a fine step between the upper surface of the first supporter 400 and the upper surface of the first lower electrode 300.

Meanwhile, although the first supporter film 400p is illustrated as remaining in the third region III, the technical idea of the present inventive concept is not limited thereto. Thus, the first supporter film 400p may be removed from all the first to third regions I, II and III.

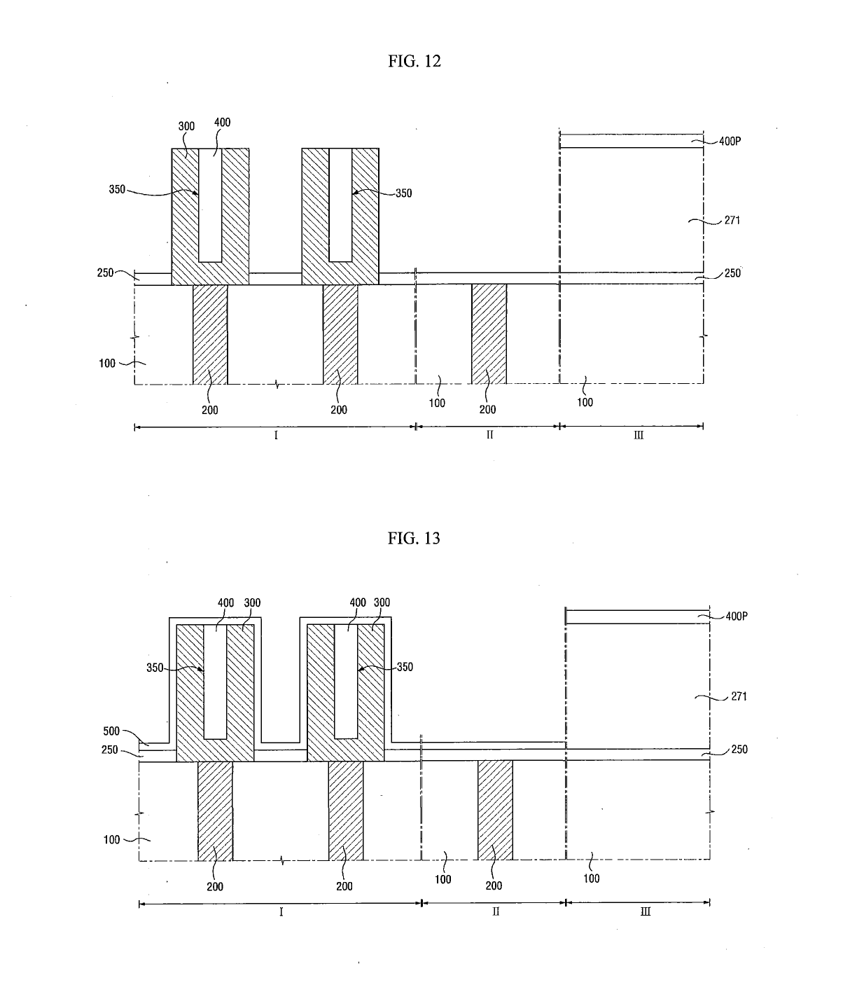

Referring to FIG. 12, all the remaining mold oxide 271 of first and second regions I and II is etched. Thus, only the etching stop film 250 remains on the side surfaces of the first lower electrode 300, and thus, outer walls of the first lower electrode 300 may be exposed. Collapse of the first lower electrode 300 may be prevented using the first supporter 400.

Meanwhile, the mold oxide 271 of the third region III may remain. Thus, it is possible to prevent particles such as dust from being diffused into the first and second regions I and II.

Next, referring to FIG. 13, in the first and second regions I and II, a dielectric film 500 may be formed to cover all of the etching stop film 250, the first lower electrode 300 and the first supporter 400. The dielectric film 500 may be formed of Al₂O₃, HfO2, lantanide oxide, ZrO₂, Ta₂O₅, TiO₂, SrTiO3, BaSrTiO3 and combinations thereof.

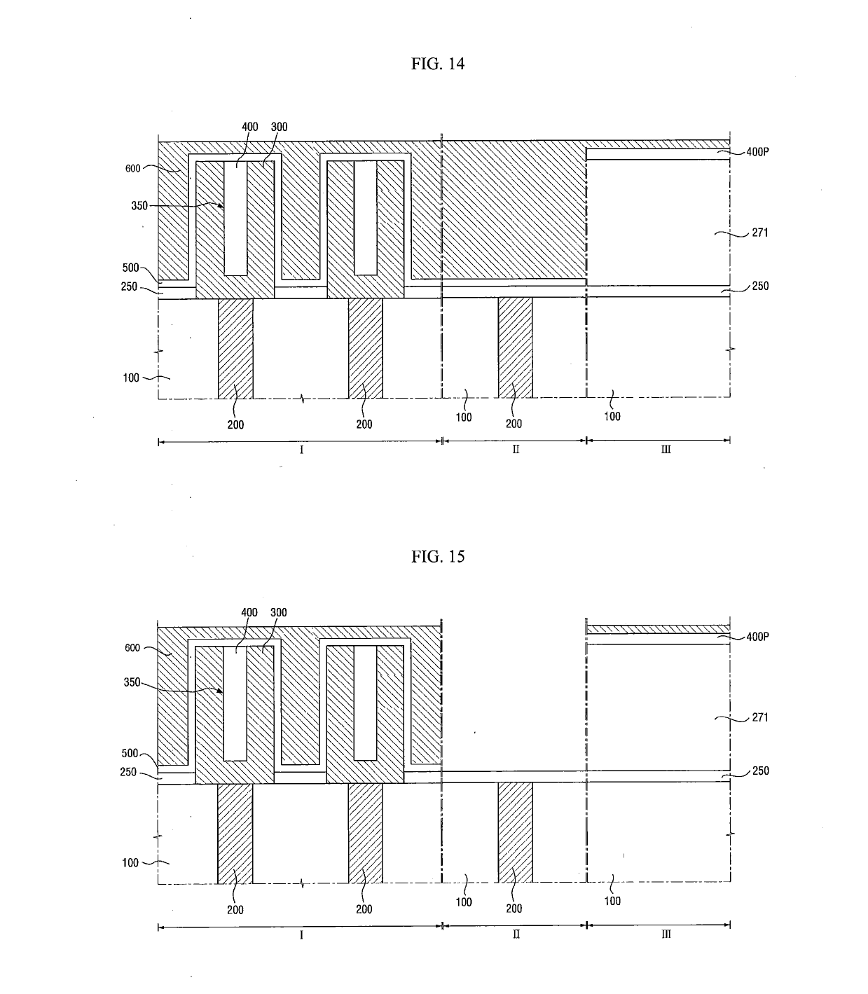

Next, referring to FIG. 14, the upper electrode 600 may be formed on the dielectric film 500. The upper electrode 600 may use TiN, TaN, W, Ru, Pt or the like.

The upper electrode 600 may be formed on all of the first to third regions I, II and III, but it is not limited thereto.

Meanwhile, the first lower electrode 300, the dielectric film 500 and the upper electrode 600 may form a capacitor to serve as a storage element. The capacitor of the present embodiment may be used to perform the role of a storage element of a dynamic random access memory (DRAM), but it is not limited thereto. That is, it may also be used in manufacturing of a general capacitor.

Next, referring to FIG. 15, the upper electrode 600 formed in the second region II is removed. Thus, the etching stop film 250 of the second region II may be exposed to the outside.

More specifically, a mask film is formed on other regions except the second region II, and the upper electrode 600 formed on the second region II may be removed and etched. However, it is not limited thereto.

Meanwhile, in some embodiments of the present inventive concept, all or a part of the upper electrode 600 disposed on the third region II may also be removed.

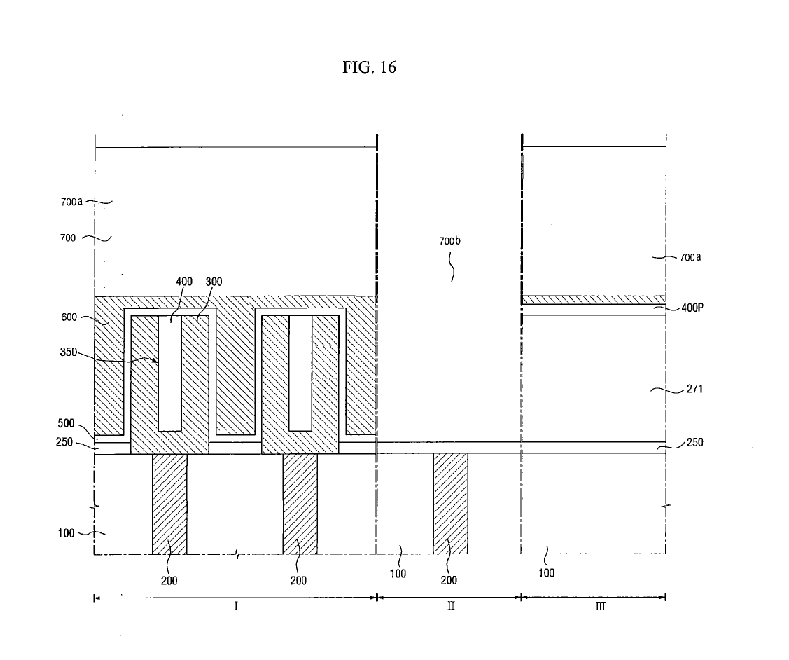

Next, referring to FIG. 16, an upper interlayer insulating film 700 is formed in the first to third regions I, II and III.

The upper interlayer insulating film 700 may form a step depending on the height difference among the first to third regions I, II and III.

Accordingly, the upper interlayer insulating film 700 disposed on the second region II may include a step due to a height difference with the upper interlayer insulating film 700 disposed on the first and third regions I and III adjacent thereto.

In this embodiment, the upper interlayer insulating film 700 of the higher height of the upper interlayer insulating film 700 may be referred to as a high step portion 700a, and the upper interlayer insulating film 700 of the lower height of the upper interlayer insulating film 700 may be referred to as a low step portion 700b.

That is, the high step portion 700a of the upper interlayer insulating film 700 may be formed in the first and third regions I and III, and the low step portion 700b may be formed of the upper interlayer insulating film 700 may be formed on the second region II.

The upper interlayer insulating film 700 may be formed, using a silicon oxide such as borosilicate glass (BSG), phosphosilicate glass (PSG), borophosphosilicate glass (BPSG), undoped silicate glass (USG), tetraethylorthosilicate glass (TEOS) and/or high density plasma-CVD (HDP-CVD).

Through the processes up to FIG. 16, the step corresponding to the height difference among the first to third regions I, II and III is formed on the wafer.

Therefore, for the subsequent steps for manufacturing the semiconductor device, there is a need for a flattening process that constantly adjusts the heights of each region (e.g., first to third regions I, II and III of the present inventive concept). When a reliable flattening process is performed, the reliability of the manufacturing process of the semiconductor device may also be improved, and eventually, a highly reliable semiconductor device may be manufactured.

In the common manufacturing process of the semiconductor device, heights of various regions on the wafer may be different. Thus, the methods of manufacturing the semiconductor device of the present inventive concept described below may be applied to flattening of the height difference of the various regions on the wafer.

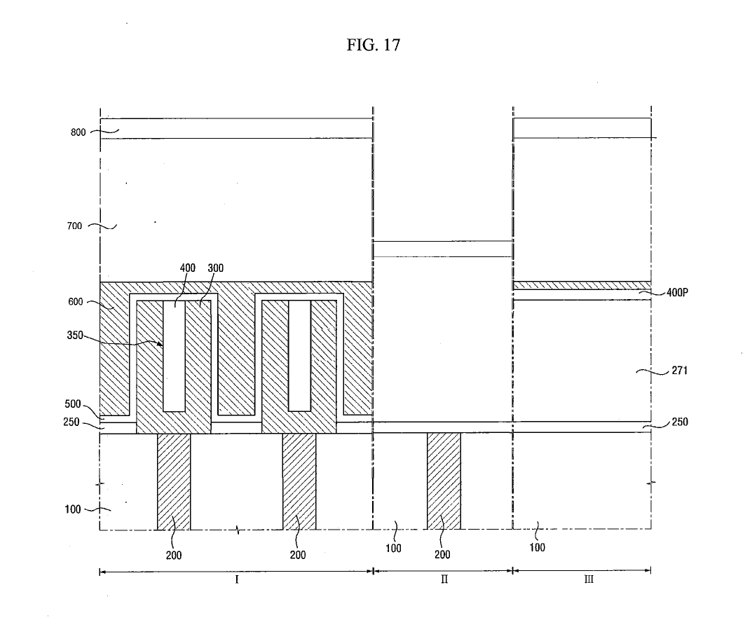

Next, methods of flattening a wafer included in the method of manufacturing the semiconductor device of the present inventive concept will be described through FIGS. 17 to 21.

Referring to FIG. 17, an organic film 800 is formed on the upper interlayer insulating film 700. The organic film 800 may be formed on the upper interlayer insulating film 700 over the first to third regions I, II and III. The organic film 800 may be conformally formed on the upper interlayer insulating film 700 to have a uniform thickness.

In this embodiment, the thickness of the organic film 800 is not limited to an illustrated thickness, and may be formed to have various thicknesses if desired.

Meanwhile, in this embodiment, the first to third regions I, II and III may be regions connected to one another, and in this case, the organic film 800 may be formed on the sidewalls of the high step portion 700a.

The organic film 800 may be an organic film that contains no silicon. However, it is not limited thereto.

The organic film 800 may be formed on the upper interlayer insulating film 700 using a spin coating method. However, it is not limited thereto.

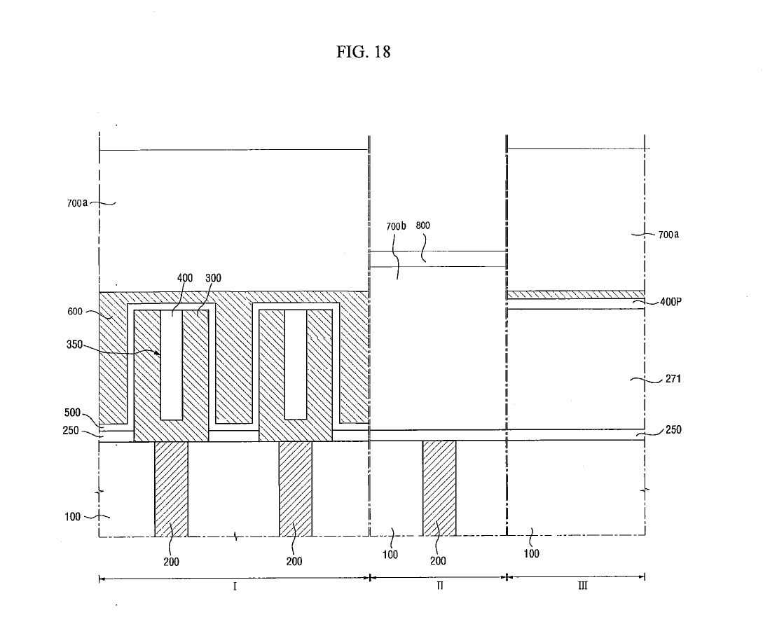

Next, referring to FIG. 18, the organic film 800 formed on the first and third regions I and III is removed. Thus, the upper surface of the upper interlayer insulating film 800 formed on the first and third regions I and III may be exposed.

Specifically, the upper surface of the high step portion 700a of the first and the third region I and III may be exposed. Meanwhile, as described above, when the first to third regions I, II and III are regions connected to each other, the organic film 800 may be formed on the sidewalls of the high step portion 700a. Thus, in some embodiments of the present inventive concept, the organic film 800 formed on the sidewalls may not be removed.

Meanwhile, the organic film 800 may be removed through a chemical mechanical polishing process. Specifically, the organic film 800 formed on the upper surface of the high stage portion 700a is removed through the chemical mechanical polishing process, and the chemical mechanical polishing process may be stopped due to the upper interlayer insulating film 700.

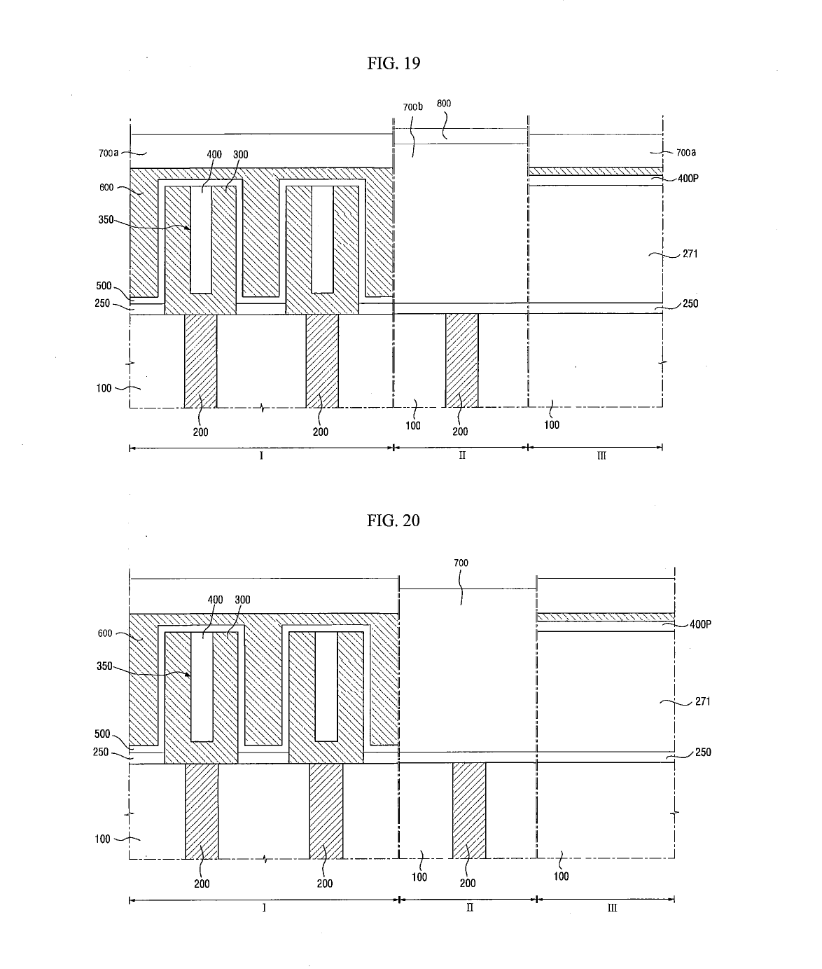

Next, referring to FIG. 19, the upper interlayer insulating film 800 formed on the first and third regions I and III is partially removed.

Specifically, until the upper surface of the high step portion 700a formed in the first and third regions I and III is disposed at least below the upper surface of the organic film 800 of the second region II, the upper interlayer insulating film 700 may be etched. However, the technical idea of the present inventive concept is not limited thereto.

The upper interlayer insulating film 700 may be etched through wet etching or dry etching. In this embodiment, the upper interlayer insulating film 700 may be etched through anisotropic etching, but it is not limited thereto. Accordingly, the upper interlayer insulating film 700 may also be etched through the isotropic etching.

Next, referring to FIG. 20, the organic film 800 disposed on the second region II is removed. The organic film 800 may be removed using ashing and strip. However, it is not limited thereto.

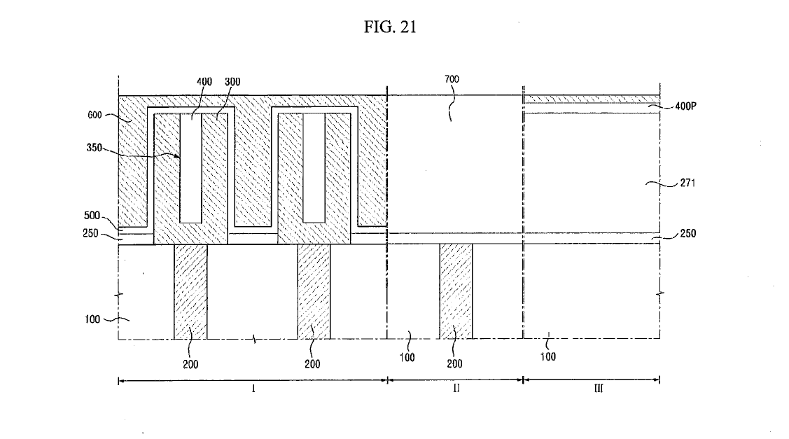

Next, referring to FIG. 21, the upper interlayer insulating film 700 is flattened.

Specifically, the upper interlayer insulating film 700 may be flattened through the chemical mechanical polishing process. Thus, it is possible to eliminate the step of the first to third regions I, II and III and make the regions entirely flat.

The upper interlayer insulating film 700 formed on the first and third regions I and III is removed, and the upper surface of the upper interlayer insulating film 700 formed on the second region II may be formed to be disposed on the same plane as the upper surface of the upper electrode 600 formed in the first region I. Also, the upper surface of the upper interlayer insulating film 700 formed on the second region II may be formed to be disposed on the same plane as the upper surface of the third region III.

That is, the upper surfaces of the first to third region I, II and III of the wafer may be formed on the same plane. The “same plane” is a concept that includes a fine step of each upper surface of the first to third regions I, II and III.

In the present inventive concept, the chemical mechanical polishing process on the upper interlayer insulating film 800 is limited to the process of FIG. 21 described above. That is, in the present inventive concept, since the chemical mechanical polishing process is performed after the etching process using the organic film to eliminate the step of the upper interlayer insulating film 800, the time of the chemical mechanical polishing process is relatively short. Therefore, it is possible to solve problems of the dispersion failure and the high cost associated with the chemical mechanical polishing process of a long time.

Furthermore, since the chemical mechanical polishing process is performed after forming a predetermined flatness on the upper surface of the wafer by the use of an etching process using an organic film, it is possible to maintain the same removal rate throughout the wafer. That is, it is possible to prevent a difference in removal rate due to the density differences of each wafer region.

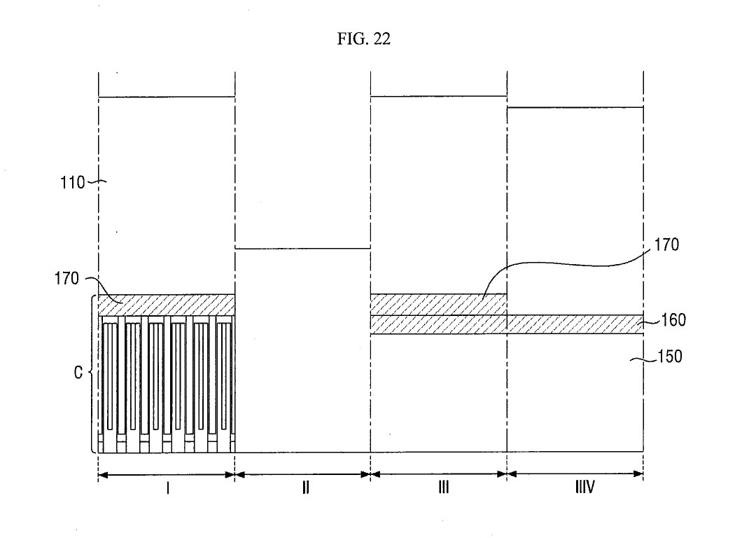

Methods of manufacturing the semiconductor device according to some other embodiments of the present inventive concept will be described referring to FIGS. 22 to 27.

FIG. 22 to FIG. 27 are cross-sectional views of intermediate operations for illustrating methods of manufacturing a semiconductor device according to some embodiments of the present inventive concept.

The methods of manufacturing a semiconductor device according to these embodiments are substantially the same as the methods of manufacturing the semiconductor device described through FIGS. 6 to 21 except that the former includes a fourth region. Therefore, the repeated description may be omitted.

Referring to FIG. 22, the first region I of FIG. 22 may correspond to the first region II of FIG. 16, and the second region II of FIG. 22 may correspond to the second region II of FIG. 16. Further, the third region III of FIG. 22 may correspond to the third region III of FIG. 16.

Specifically, thus, the upper metal electrode layer 170 on the capacitor region C may correspond to the upper electrode 600 of FIG. 16, and the edge insulating film 160 may correspond to the supporter film 400p of FIG. 16. Further, the wafer interlayer insulating film 110 may correspond to the upper interlayer insulating film 700 of FIG. 16. In addition, the oxide layer 150 may correspond to the mold oxide layer 271 of FIG. 16.

Meanwhile, the capacitor region C may be a memory cell array region that includes a memory cell array.

In this example, a fourth region IV may be further formed on the wafer. Unlike the third region III, the fourth region IV may not include the upper metal electrode layer 170.

In some embodiments, the first and second regions I and II may be a main region in the wafer. The first region I may be a memory cell array region, and the second region II may be a peripheral region or a core/peri region. The third and fourth regions III and IV may be edge regions of the wafer and may be PSES regions. The third region III may be a cell region of the wafer edge region, and the fourth region IV may be a peripheral region of the wafer edge region or a core/peri region. However, it is not limited thereto.

In the manufacturing process of the semiconductor device, processes are performed on the front surface of the wafer. That is, the first and third regions I and III may be regions in which the process of forming the cell is performed, and the second and fourth regions II and IV may be regions in which the process of forming the core/peri is performed. However, in this case, a substantial formation process may be performed on the first and second regions I and II, and the third and fourth regions III and IV may be PSES regions of the wafer edge in which a pattern is not formed. However, it is not limited thereto.

Referring to FIG. 22 again, a wafer interlayer insulating film 110 is formed in the first to fourth regions I, II III and IV. In this case, a low step portion may be formed in the second region II, and a high step portion may be formed in the first, third and fourth regions I, III and IV.

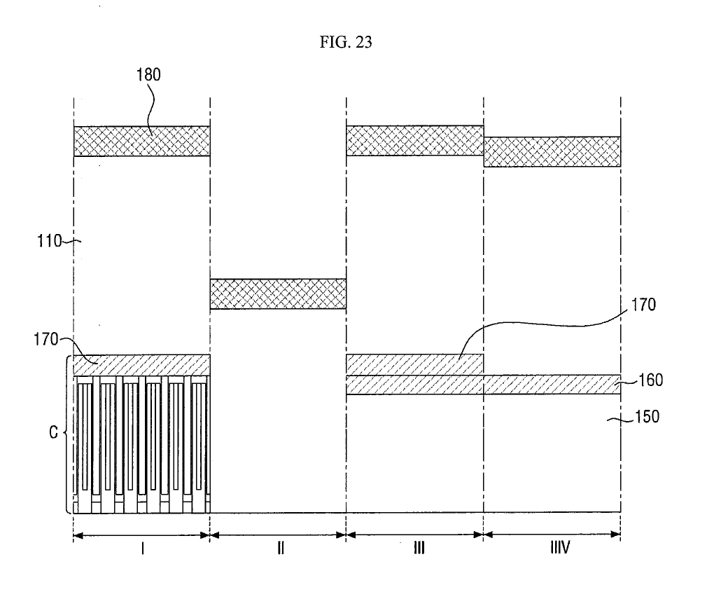

Next, referring to FIG. 23, a wafer organic film 180 is conformally formed on the wafer interlayer insulating film 110.

The intermediate operations according to FIG. 23 may correspond to the intermediate operations of FIG. 17. Thus, the wafer organic film 180 may correspond to the organic film 800 of FIG. 17.

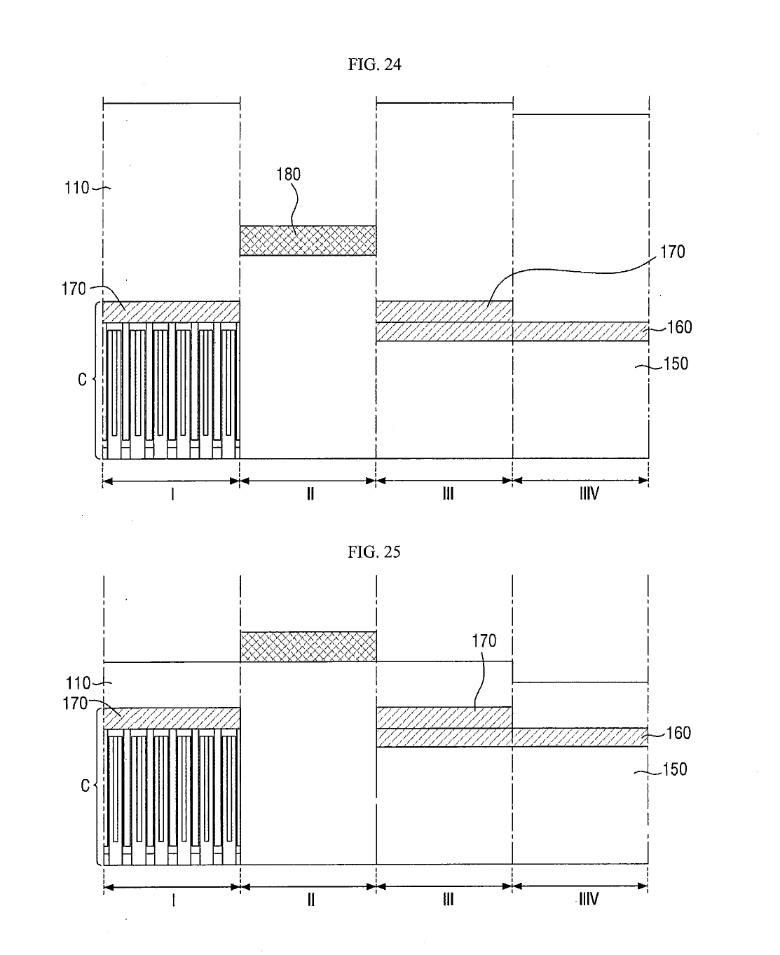

Next, referring to FIG. 24, with the exception of the wafer organic film 180 of the second region II, the wafer organic film 180 of the first, third and fourth regions I, III and IV is removed. The intermediate operations of FIG. 24 may correspond to the intermediate operations of FIG. 18. Therefore, the repeated description may be omitted.

Referring to FIG. 24, the wafer interlayer insulating film 110 of the first, third and fourth regions I, III and IV is etched. The intermediate operations according to FIG. 24 may correspond to the intermediate operations according to FIG. 19.

Meanwhile, in this embodiment, since the fourth region IV does not include the upper metal electrode layer 170, a relatively low height of the wafer interlayer insulating film 110 may be formed as compared to the other regions I, II and III. However, it is not limited thereto.

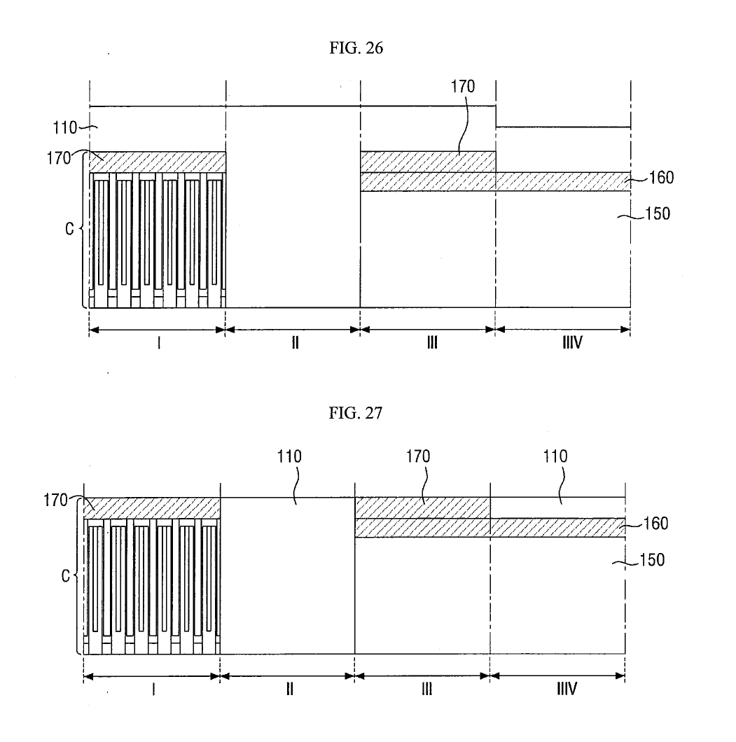

Referring to FIG. 26, the wafer organic film 180 formed on the second region II is removed, and referring to FIG. 27, a flattening process of the wafer organic film 180 is performed. The intermediate operations of FIGS. 26 and 27 may correspond to the intermediate operations of FIGS. 20 and 21.

Referring to FIG. 27 again, as illustrated, the upper surfaces of each of first to fourth regions I, II III and IV may be formed on the same plane. Here, the “same plane” is a concept that includes a fine step of the upper surfaces of each of the first to fourth regions I, II III and IV.

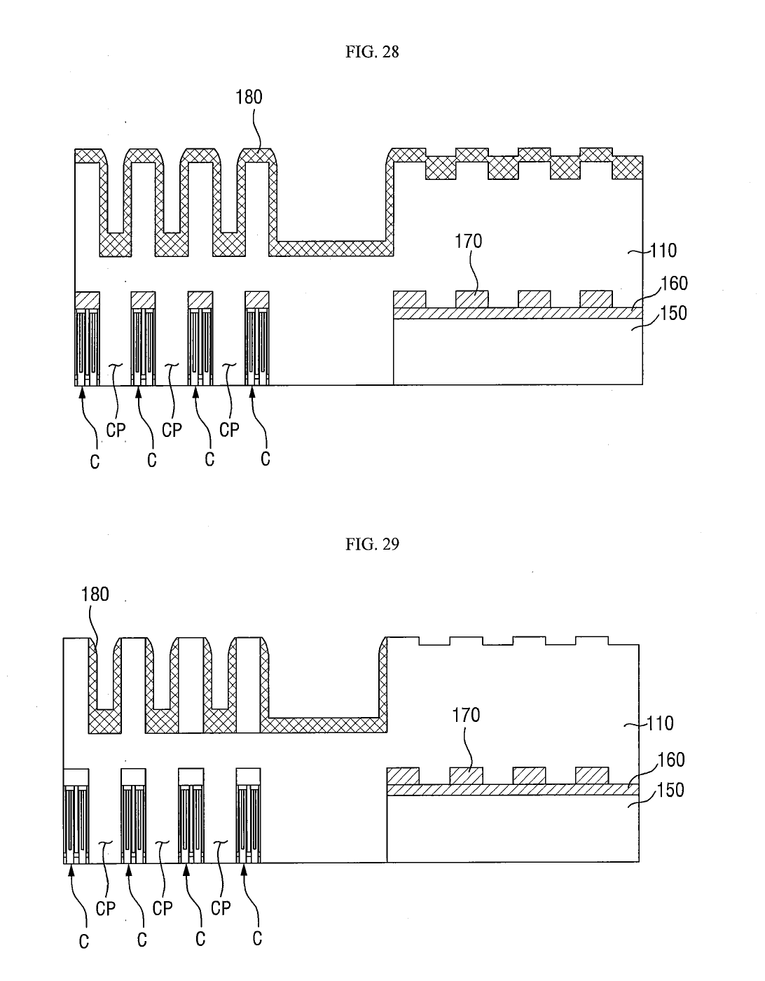

Next, methods of manufacturing a semiconductor device according to some embodiments of the present inventive concept will be described with reference to FIGS. 28 to 32.

FIGS. 28 to 32 are cross-sectional views of intermediate operations for illustrating methods of manufacturing a semiconductor device according to some embodiments of the present inventive concept.

The cross-sectional views according to some embodiments may be cross-sectional views illustrating a region on the wafer, in the semiconductor manufacturing process.

That is, the methods of manufacturing the semiconductor device according to some embodiments may include a plurality of memory cell array regions and a plurality of peripheral regions, as compared to other methods of manufacturing the semiconductor device described above. Therefore, as compared to the embodiment described through FIGS. 22 to 27, since the same reference numerals refer to the same elements, the repeated description of the same constituent elements may be omitted.

Referring to FIG. 28, a plurality of memory cell array regions C may be disposed, and a peripheral region CP may be disposed between the memory cell array regions C. In some embodiments, the plurality of memory cell array regions C and the plurality of peripheral regions CP may form a first region. Also, a region in which the oxide layer 150 is formed may be a third region, and a region between the first region and the third region may be a second region.

Referring to FIG. 28, the wafer organic film 180 is conformally formed on the wafer interlayer insulating film 110.

Next, referring to FIG. 29, a part of the wafer organic film 180 is removed to expose the upper surface of the wafer interlayer insulating film 110. In some embodiments, a wafer interlayer insulating film 110 has a step depending on the region to be formed, and thus, the wafer organic film 180 may be formed on the sidewalls of the wafer interlayer insulating film 110.

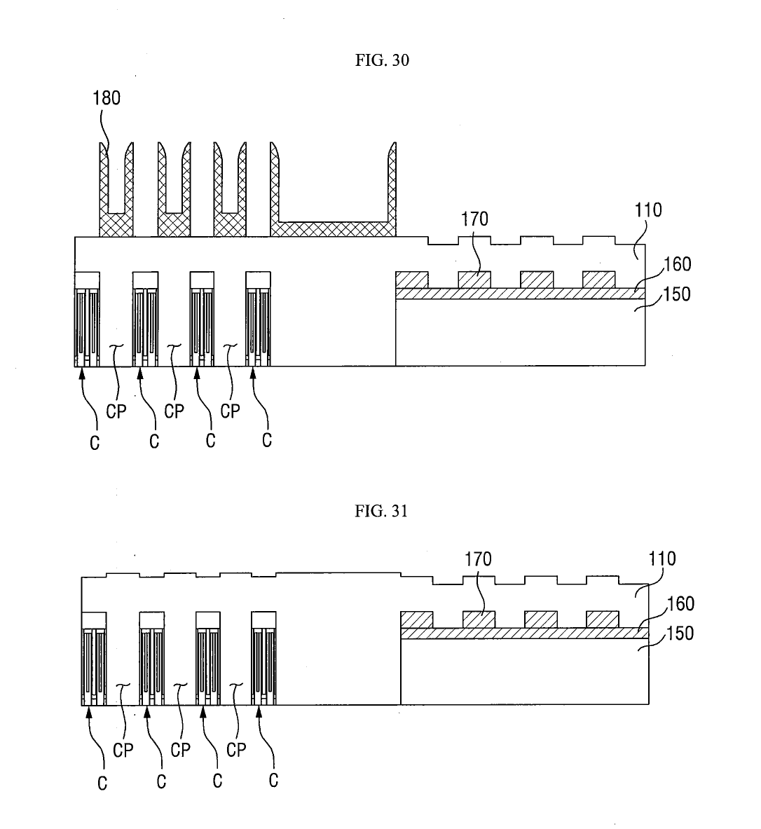

Referring to FIG. 30, the wafer interlayer insulating film 110 disposed between the wafer organic films 180 is removed.

Next, referring to FIG. 31, the wafer organic film 180 is removed to expose the upper surface of the wafer interlayer insulating film 110.

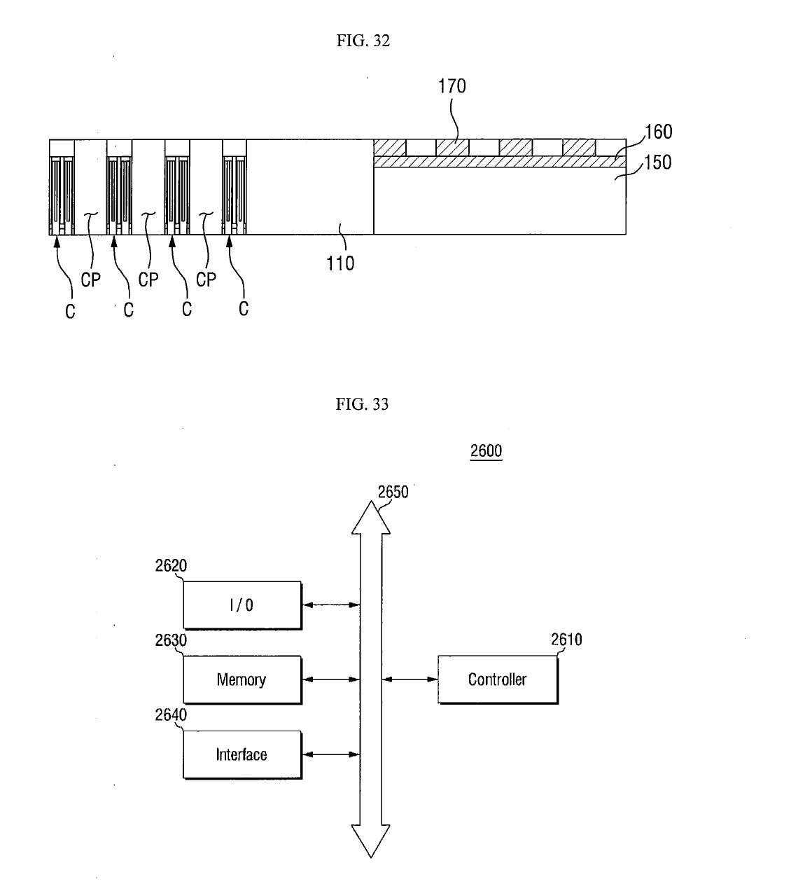

Referring to FIG. 32, the wafer interlayer insulating film 110 is flattened.

Thus, the flat upper surface of the wafer may be flattened using the methods of manufacturing the semiconductor according to the present inventive concept.

FIG. 33 is an example block diagram of an electronic system including the semiconductor device manufactured by methods of manufacturing the semiconductor device according to some embodiments of the present inventive concept.

Referring to FIG. 33, an electronic system 2600 according to some embodiments of the present inventive concept may include a controller 2610, an input/output (I/O) device 2620, a memory device 2630, an interface 2640 and a bus 2650. The controller 2610, the I/O device 2620, the memory device 2630 and/or the interface 2640 may be connected to one another through a bus 2650. The bus 2650 corresponds to a path through which the data are moved.

The controller 2610 may include at least one of a microprocessor, a digital signal processor, a microcontroller and logic elements capable of performing similar functions to the elements. The I/O device 2620 may include a keypad, a keyboard, a display device and the like. The memory device 2630 may store data and/or commands. The memory device 2630 may include semiconductor elements according to some embodiments of the present inventive concept. The memory device 2630 may include a DRAM. The interface 2640 may serve to transmit data or receive data to and from a communication network. The interface 2640 may be a wired or wireless interface. In an example, the interface 2640 may include an antenna or a wired or wireless transceiver.

The electronic system 2600 may be applied to a personal digital assistant (PDA), a portable computer, a web tablet, a wireless phone, a mobile phone, a digital music player and/or a memory card and/or all types of electronic products capable of transmitting or receiving information in a wireless environment.

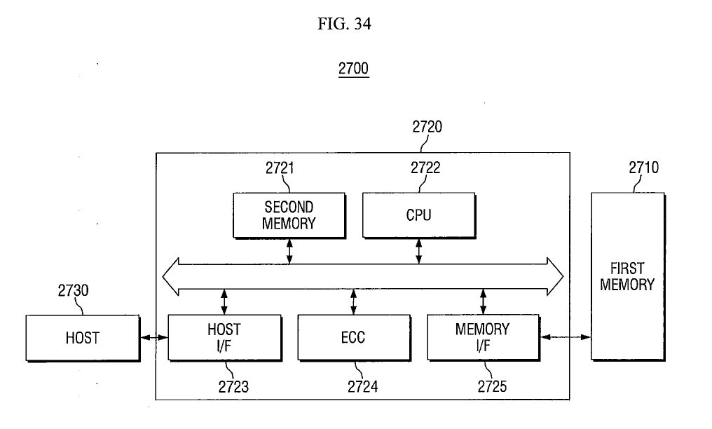

FIG. 34 is a block diagram illustrating an example of a memory card that includes a semiconductor device manufactured by methods of manufacturing the semiconductor device according to the embodiments of the present inventive concept.

Referring to FIG. 34, a first memory 2710 including the semiconductor device manufactured according to the various embodiments of the present inventive concept may be adopted in a memory card 2700. The memory card 2700 may include a memory controller 2720 that controls the data exchange between a host 2730 and the first memory 2710.

The second memory 2721 may be used as an operation memory (Cache Memory) of a central processing unit 2722. The second memory 2721 may include the semiconductor elements according to some embodiments of the present inventive concept. A host interface 2723 may include a protocol that allows the host 2730 to be connected to the memory card 2700 for exchanging the data. An error correction code 2724 may detect and correct errors of the data read from the first memory 2710. The memory interface 2725 may interface with the first memory 2710. The central processing unit 2722 may perform the overall control operations related to the data exchange of the memory controller 2720.

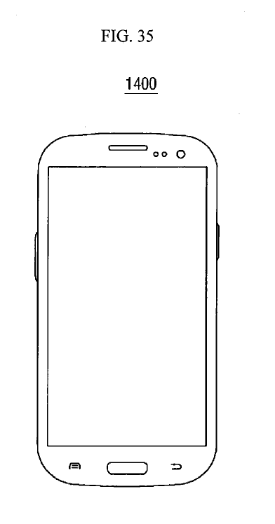

FIG. 35 is an example semiconductor system to which the semiconductor devices according to some embodiments of the present inventive concept are applicable. FIG. 35 illustrates a smart phone. It will be obvious to those skilled in the art that the semiconductor device according to some embodiments of the present inventive concept may also be applied to other integrated circuit devices that are not illustrated.

While the present inventive concept has been particularly illustrated and described with reference to exemplary embodiments thereof, it will be understood by those of ordinary skill in the art that various changes in form and detail may be made therein without departing from the spirit and scope of the present inventive concept as defined by the following claims. The example embodiments should be considered in a descriptive sense only and not for purposes of limitation.

What is claimed is:

1. A method of manufacturing a semiconductor device, the method comprising:
forming, on a substrate, first to third regions having densities that are different from one another;
covering the first to third regions to form an upper interlayer insulating film including a low step portion and a high step portion that is higher than the low step portion;
forming an organic film on the upper interlayer insulating film;
removing a part of the organic film to expose an upper surface of the high step portion;
removing the high step portion so that an upper surface of the high step portion is at least the same height as a portion of the organic film on the upper surface of the lower step portion;
removing the remaining part of the organic film to expose the upper surface of the upper interlayer insulating film; and
flattening the upper surface of the upper interlayer insulating film.

2. The method of claim 1, wherein the organic film does not contain silicon (Si).

3. The method of claim 1, wherein the formation of the organic film comprises conformally forming the organic film on the upper interlayer insulating film.

4. The method of claim 1, wherein the first region has a density that is lower than a density of the third region,
wherein the first region is a memory cell array region, and
wherein the third region is a wafer edge region.

5. The method of claim 4, wherein the flattening of the upper surface of the upper interlayer insulation film comprises disposing the upper surface of the memory cell array and the upper surface of the upper interlayer insulating film on a same plane.

6. The method of claim 1, wherein the removal of a part of the organic film comprises removing a part of the organic film through chemical mechanical polishing process.

7. The method of claim 1, wherein the formation of the upper interlayer insulating film comprises forming the low step portion on the second region and forming the high step portion on the third region.

8. The method of claim 1, wherein the removal of the high step portion comprises removing the high step portion by etching.

9. The method of claim 8, wherein the removal of the high step portion comprises removing the high step portion by anisotropic etching.

10. The method of claim 1, wherein flattening of the upper surface of the upper interlayer insulation film comprises flattening the upper surface of the upper interlayer insulating film through a chemical mechanical polishing process.

11. A method of manufacturing a semiconductor device, the method comprising:
forming a memory cell array region, a peripheral region and a wafer edge region on a substrate;
forming an interlayer insulating film that covers the memory cell array region, the peripheral region and the wafer edge region;
forming an organic film on the interlayer insulating film;
removing the organic film disposed in the memory cell array region and the wafer edge region to expose a part of an upper surface of the interlayer insulating film;
etching a part of the interlayer insulating film so that the partial upper surface of the interlayer insulating film covering the memory cell array region and the wafer edge region is disposed below an upper surface of the organic film disposed in the peripheral region;
removing the organic film disposed in the peripheral region; and
flattening the interlayer insulating film formed in the memory cell array region, the peripheral region and the wafer edge region.

12. The method of claim 11, wherein the organic film does not contain silicon (Si).

13. The method of claim 11, wherein the removal of the organic film in the memory cell array region and the wafer edge region comprises using a chemical mechanical polishing process.

14. The method of claim 11, wherein etching of the interlayer insulation film comprises an anisotropic etching using a dry etching.

15. The method of claim 14, wherein flattening of the interlayer insulating film comprises use of a chemical mechanical polishing process.

16. A method of manufacturing a semiconductor device, the method comprising:
forming an interlayer insulating film that covers a plurality of regions having different densities from one another;
forming an organic film on the interlayer insulating film;
removing the organic film from less than all of the plurality of regions to expose a portion of an upper surface of the interlayer insulating film;
etching a part of the interlayer insulating film so that the partial upper surface of the interlayer insulating film is at a height that is below an upper surface of the organic film on at least one of the plurality of regions;
removing the organic film from the at least one of the plurality of regions; and
flattening the upper surface of the interlayer insulating film on the plurality of regions.

17. The method of claim 16, wherein the organic film does not contain silicon (Si), and
wherein the formation of the organic film comprises conformally forming the organic film on the upper interlayer insulating film.

18. The method of claim 16, wherein the less than all of the plurality of regions have a first density and the at least one of the plurality of regions has a second density that is greater that the first density.

19. The method of claim 16, wherein flattening the upper surface of the upper interlayer insulation film comprises flattening the upper surface of the upper interlayer insulating film by performing a chemical mechanical polishing process.

20. The method of claim 16, wherein etching the part of the interlayer insulation film comprises anisotropically etching the part of the interlayer insulating film using a dry etching.
